(19) United States
(12) Patent Application Publication
(10) Pub. No.: US 2014/0251668 A1
(43) Pub. Date: Sep. 11, 2014

(54) AUTOMATIC MANUFACTURING PROCESS FOR PROVIDING BUFFER PADS FOR A PCB AND PCB STRUCTURE USING THE SAME

(71) Applicant: DELTA ELECTRONICS, INC., Taoyuan County (TW)

(72) Inventors: Chun-Kai CHUANG, Taoyuan County (TW); Yu-Wei LEE, Taoyuan County (TW); Kuo-Liang LEE, Taoyuan County (TW)

(73) Assignee: DELTA ELECTRONICS, INC., Taoyuan County (TW)

(21) Appl. No.: 13/969,940

(22) Filed: Aug. 19, 2013

(30) Foreign Application Priority Data
Mar. 7, 2013 (TW) 102107993

(51) Int. Cl. H05K 3/30; H05K 1/18

(52) U.S. Cl. CPC H05K 3/305; H05K 1/181
USPC 174/260; 29/832

(57) ABSTRACT

An automatic manufacturing process for providing buffer pads (40) for a PCB (10), includes a) providing the PCB (10); b) providing an automatic dispensing device and an adhesive (30); c) using the automatic dispensing device to dispense the adhesive (30) to a buffer zone (12) on the PCB (10); d) providing a pick-and-place machine and the buffer pads (40); e) using the pick-and-place machine to place the buffer pads (40) on the buffer zone (12) moistened with the adhesive (30); and f) curing the adhesive (30) to attach the buffer pads (40) to the PCB (10). Thus, labor is saved and manufacturing time is reduced.

### BACKGROUND OF THE INVENTION

1. Field of the Invention

The present invention relates to a buffer pad used in a printed circuit board (PCB) and in particular to a method of attaching the buffer pad to a PCB using an automatic pick-and-place machine.

2. Description of Related Art

Many electronic components such as capacitors, resistors, and electrical connectors, are generally disposed on a PCB. These electronic components are attached to the PCB using SMT (Surface Mount Technology) or traditional DIP (Dual in-line Package), in which SMD (Surface Mount Device) type electronic components are soldered horizontally to the PCB using SMT process. In addition to a smaller occupied area and less PCB material cost, no through-hole machining is required such that efficiency of PCB layout is increased and thus the number of layers of the PCB is decreased.

In use, the PCB is generally disposed within an external shell. Lead frames of some electronic components in the PCB are easy to cause damage to the external shell and thus plastic/rubber is widely used as a material of a buffer pad in current industry. The embodiment is achieved by applying a twin adhesive to the bottom of the buffer pad and then placing the buffer pad to adhere to the PCB. As such, the buffer pad is used as a support structure between the PCB and the external shell, and provides a buffer mechanism between them.

However, the current placement of the above buffer material is performed by manual adhering operation. As a result, it is time-consuming and labor-intensive and can not meet the requirement of modern automation engineering. Also, the stickiness of the twin adhesive may decay over time, causing the buffer material to fall out.

In view of this, the inventor pays special attention to research with the application of related theory to achieve the above objective. Finally, the present invention which is a reasonably design and is able to overcome the above disadvantage is proposed.

### SUMMARY OF THE INVENTION

One objective of the present invention is to provide an automatic manufacturing process for providing buffer pads for a PCB in order to save labor and time, and achieve the effect of shortening the manufacturing process.

To achieve the above objective, the present invention provides an automatic manufacturing process for providing buffer pads for a PCB. The automatic manufacturing process comprises a) providing the PCB; b) providing an automatic dispensing device and an adhesive; c) using the automatic dispensing device to dispense the adhesive to a buffer zone on the PCB; d) providing a pick-and-place machine and the buffer pads; e) using the pick-and-place machine to place the buffer pads on the buffer zone moistened with the adhesive; and f) curing the adhesive to attach the buffer pads to the PCB. In this way, the effects of automatic manufacturing process and saving on labor can be achieved.

Another objective of the present invention is to provide a PCB having a buffer pad which is used as a support structure of the PCB and provides a buffer mechanism.

To achieve the above objective, the present invention provides a PCB device comprising a PCB, at least one SMT electronic component, an adhesive, and at least one buffer pad. The PCB comprises at least one electrical connection zone and at least one buffer zone. The SMT electronic component is attached on the electric connection zone. The adhesive is disposed on the buffer zone. The buffer pad is made of a high-temperature resistant and anti-shock material and is sticked securely to the buffer zone via the adhesive.

The present invention has the following advantages. The present invention uses an automatic dispensing device to dispense the adhesive on the PCB and then uses a pick-and-place machine to moves the buffer pad by vacuum suction. Next, the buffer pads are placed on the buffer zone moistened with the adhesive. After the adhesive has been cured, the buffer pads are securely attached to the PCB. In the present invention, the placement of the buffer pads is performed by an automatic manufacturing process, resulting in reduction in labor and process time. Moreover, compared with the related art of using the twin adhesive to secure buffer pads, the adhesive used in the present invention is a thermoplastic adhesive whose stickiness is not easily to degrade. Accordingly, the buffer pads are not easy to fall out and greater reliability is ensured.

### BRIEF DESCRIPTION OF DRAWING

FIG. 1 is a flow chart of the automatic manufacturing process for providing buffer pads for a PCB of the present invention;

FIG. 2 is a schematic view of the PCB of the present invention regarding solder paste printing;

FIG. 3 is a schematic view of the PCB of the present invention after solder paste printing;

FIG. 4 is a schematic view of the PCB of the present invention after the adhesives are dispensed;

FIG. 5 is a schematic view of the placement of the buffer pad and SMT electronic component of the present invention;

FIG. 6 is a cross-sectional view of the buffer pad and SMT electronic component of the present invention after attachment; and

FIG. 7 is a perspective view of the PCB of the present invention disposed with the buffer pads.

### DETAILED DESCRIPTION OF THE INVENTION

The detailed explanation and technique of the present invention will be described with figures as follows. However, the accompanying figures are only for reference and explanation, not to limit the scope of the present invention.

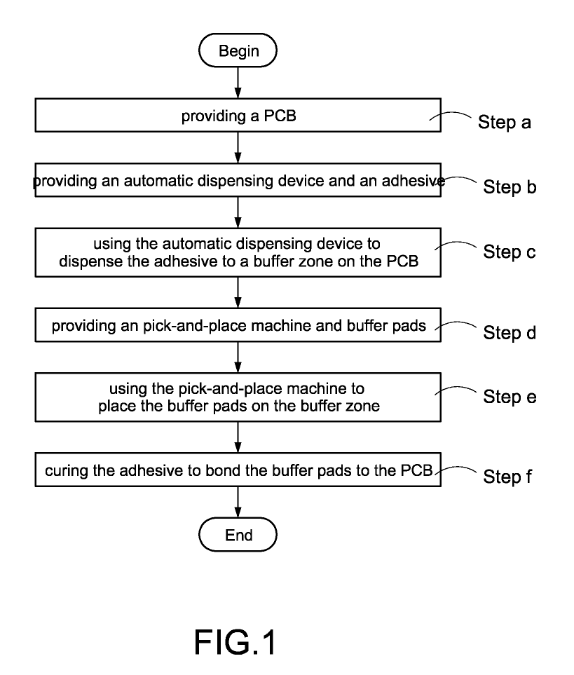

Please refer to FIG. 1, which is a flow chart of the automatic manufacturing process for providing buffer pads for a PCB of the present invention. The automatic manufacturing process for providing buffer pads for a PCB of the present invention comprises the following steps: providing a PCB (step a); providing an automatic dispensing device and an adhesive (step b); using the automatic dispensing device to dispense the adhesive to at least one buffer zone on the PCB (step c); providing a pick-and-place machine and at least one buffer pad (step d); using the pick-and-place machine to place the buffer pad on the buffer zone moistened with the adhesive (step e); and curing the adhesive to attach the buffer pads to the PCB (step f).

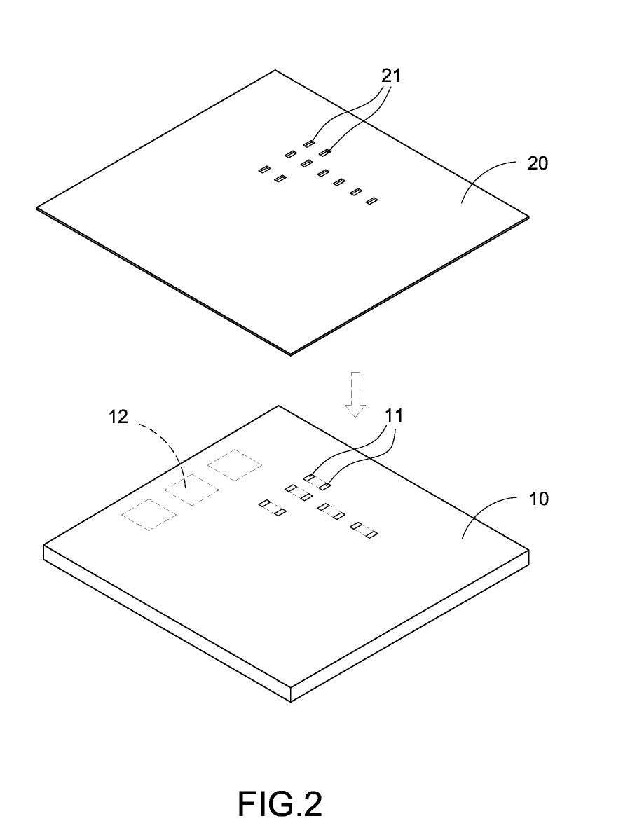

Also, please refer to FIGS. 2-4, which are schematic views of manufacturing process for providing buffer pads for a PCB. In the embodiment, in the manufacturing process for providing the buffer pads for the PCB, a PCB 10 is provided first (step a). The PCB 10 comprises a plurality of electrical connection zones 11 and at least one buffer zone 12. Next, a solder paste printing device (not shown) and solder paste (not shown) are provided. The solder paste printing device is used to print the solder paste on the electrical connection zones 11 of the PCB 10 (step a).

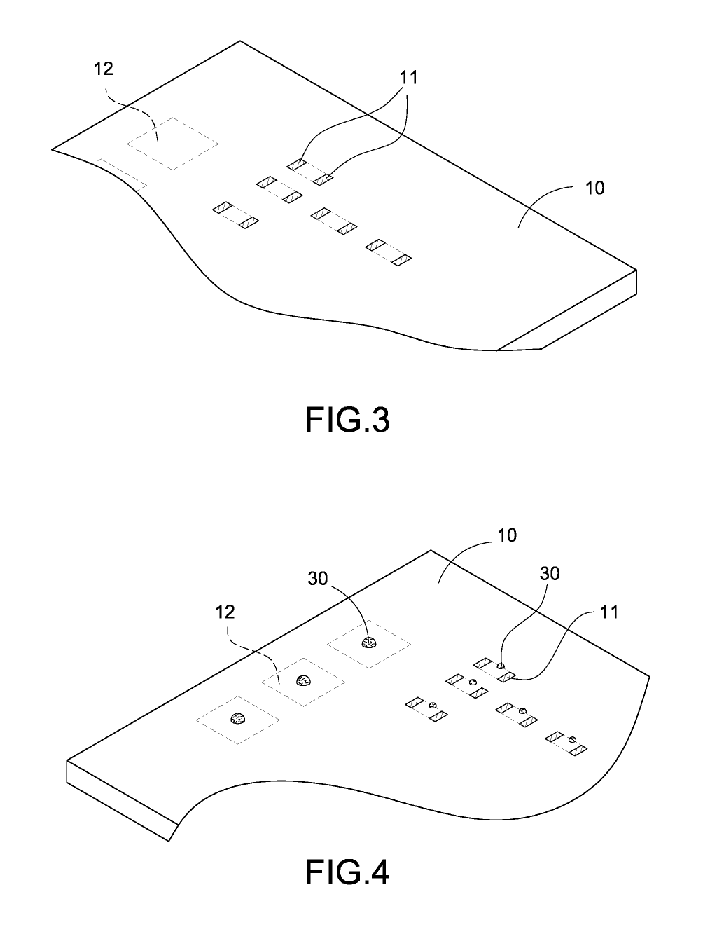

As shown in FIGS. 2 and 3, in step a, the solder paste printing device prints the solder paste on predetermined locations of the PCB 10 through a metal stencil 20. A plurality of holes 21 corresponding to the electrical connection zones 11 are formed in the metal stencil 20. In the embodiment, the locations of the holes correspond to the two ends of the electrical connection zones 11. That is, the solder paste will be printed on the two ends of the electrical connection zones 11.

Please continue to refer to FIG. 4. Next, an automatic dispensing device (not shown) and an adhesive 30 are provided (step b) and the automatic dispensing device is used to dispense the adhesive 30 to the buffer zones 12 on the PCB 10 (step c). In the embodiment, the adhesive 30 is a thermoplastic adhesive. The adhesive 30 is also disposed on one side of the electrical connection zones 11 (between the two ends of the electrical connection zones 11). The adhesive 30 disposed on one side of the electrical connection zones 11 is for temporary positioning of the electronic components, but not necessary. In practice, the disposition depends on the requirements.

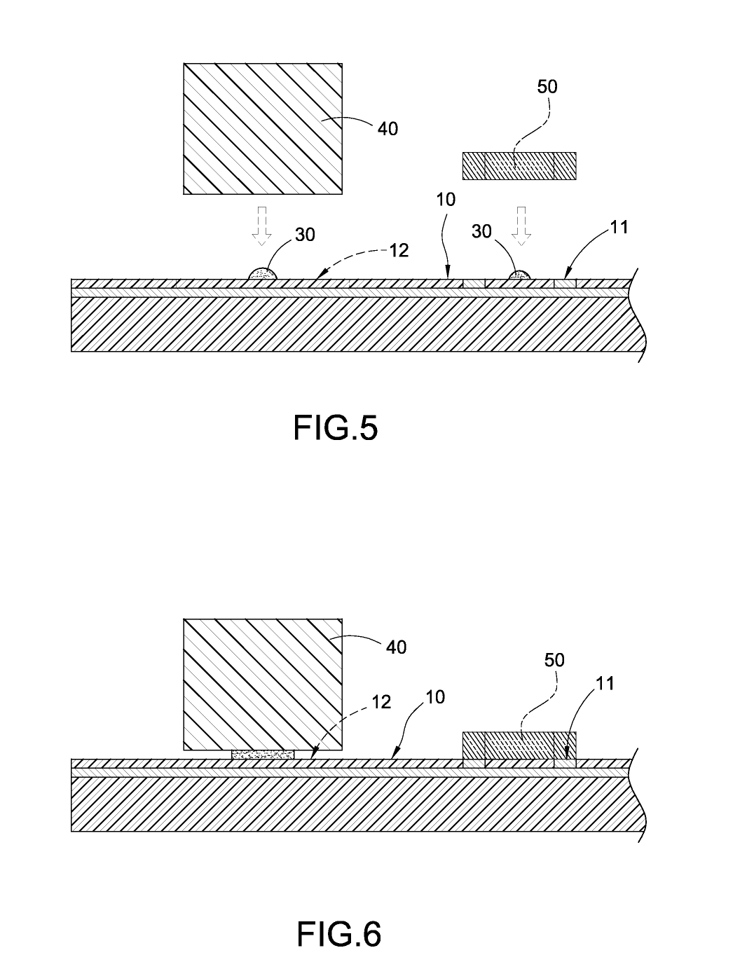

Please also refer to FIG. 5. A pick-and-place machine (not shown) and at lease one buffer pad 40 are provided (step d). In one embodiment of the present invention, the buffer pads 40 are made of a high-temperature resistant and anti-shock material. The pick-and-place machine moves the buffer pads 40 by vacuum suction and places the buffer pads 40 on the buffer zone 12 moistened with the adhesive 30 (step e). After the adhesive 30 has been cured, the buffer pads 40 can be attached to the PCB 10.

Additional description is given below. Step d further comprises providing at least one SMT electronic component 50, in which the pick-and-place machine places the SMT electronic component 50 on the PCB 10 simultaneously in step e). The pick-and-place machine can suck the buffer pads 40 and the SMT electronic component 50 simultaneously and place them at respective corresponding locations. That is, the SMT electronic component 50 is placed on the electrical connection zone 11 and the buffer pad 40 on the buffer zone 12.

Please refer to FIG. 6. Finally, the adhesive 30 is cured to attach the buffer pads 40 to the PCB 10 (step f). This step further comprises providing a reflow over (not shown) into which the PCB 10 is sent to melt the solder paste mentioned in step a and to cure the adhesive 30 at the same time. Thus, the SMT electronic components 50 can be attached to the electrical connection zones 11. Meanwhile, the buffer pads 40 are attached to the buffer zones 12 through the curing of the adhesive 30.

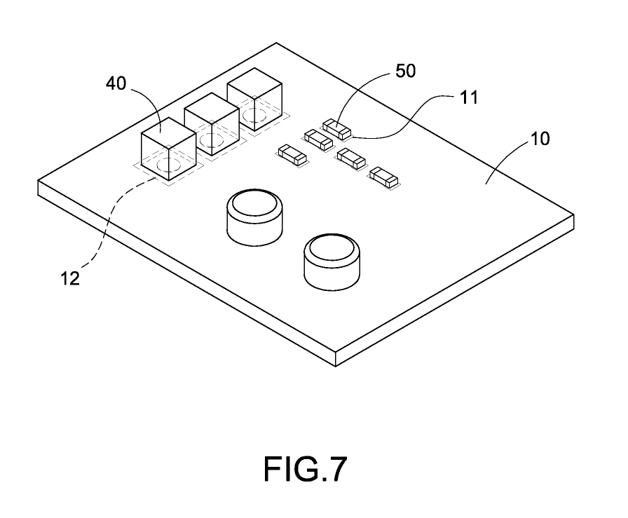

Please refer to FIG. 7 which is a perspective view of the PCB of the present invention disposed with the buffer pads. As shown in FIG. 7, the buffer pads 40 of the present invention are located on one side of the SMT electronic components 50 and the thickness of the buffer pad 40 is higher than that of the SMT electronic component 50. In this way, a buffer mechanism can be provided between the PCB 10 and the electronic components thereof.

The above description is only about preferred embodiment of the present invention, but not to limit the scope of claims of the present invention. Other equivalent variations according to the claimed spirit of the present invention should be embraced within the claimed scope of the present invention.

What is claimed is:

1. An automatic manufacturing process for providing buffer pads for a print circuit board, comprising:
a) providing the print circuit board;
b) providing an automatic dispensing device and an adhesive;
c) using the automatic dispensing device to dispense the adhesive to a buffer zone on the print circuit board;
d) providing a pick-and-place machine and the buffer pads;
e) using the pick-and-place machine to place the buffer pads on the buffer zone moistened with the adhesive; and
f) curing the adhesive to attach the buffer pads to the print circuit board.

2. The automatic manufacturing process according to claim 1, wherein step a) further comprises providing a solder paste printing device and solder paste, and using the solder paste printing device to print the solder paste on the print circuit board.

3. The automatic manufacturing process according to claim 2, wherein step a) further comprises providing a metal stencil through which the solder paste printing device prints the solder paste on the print circuit board.

4. The automatic manufacturing process according to claim 1, wherein the pick-and-place machine in step d) moves the buffer pads by vacuum suction.

5. The automatic manufacturing process according to claim 1, wherein step d) further comprises providing at least one SMT electronic component, wherein the pick-and-place machine places the SMT electronic component on the print circuit board simultaneously in step e).

6. The automatic manufacturing process according to claim 1, wherein the pick-and-place machine in step d) moves the SMT electronic component by vacuum suction.

7. The automatic manufacturing process according to claim 1, wherein the buffer pads in step d) are made of a high-temperature resistant and anti-shock material.

8. The automatic manufacturing process according to claim 1, wherein step f) further comprises providing a reflow oven into which the print circuit board is sent to cure the adhesive.

9. A printed circuit board device, comprising:
a print circuit board comprising at least one electrical connection zone and at least one buffer zone;
at least one SMT electronic component attached on the electric connection zone;
an adhesive disposed on the buffer zone; and
a buffer pad made of a high-temperature resistant and anti-shock material, the buffer pad being sticked securely to the buffer zone via the adhesive.

10. The print circuit board device according to claim 9, wherein the adhesive is disposed on one side of the electrical connection zone.

11. The print circuit board device according to claim 9, further comprising a solder paste disposed at two ends of the electrical connection zone.

12. The print circuit board device according to claim 9, wherein the adhesive is a thermoplastic adhesive.

13. The print circuit board device according to claim 9, wherein the buffer pad is disposed on one side of the SMT electronic component.

14. The print circuit board device according to claim 9, wherein a thickness of the buffer pad is higher than that of the SMT electronic component.
